(19) United States
(12) Patent Application Publication
(10) Pub. No.: US 2025/0075989 A1
(43) Pub. Date: Mar. 6, 2025

(54) LIQUID-COOLING HEAT SINK WITH TURBULENCE STRUCTURE

(71) Applicant: JWS TECHNOLOGY CO., LTD., New Taipei City (TW)

(72) Inventors: Pang-Hung LIAO, New Taipei City (TW); Chih-Wei CHEN, New Taipei City (TW); Shih-Ming WANG, New Taipei City (TW)

(21) Appl. No.: 18/240,233

(22) Filed: Aug. 30, 2023

(51) Int. Cl. F28F 13/12; H05K 7/20

(52) U.S. Cl. CPC F28F 13/12; H05K 7/20236; H05K 7/20409

(57) ABSTRACT

A liquid-cooling heat sink includes a substrate, a fin assembly, and a housing. The substrate has a longitudinal direction. The fin assembly is arranged on the substrate and includes multiple fins arranged at interval to form flow channels along the longitudinal direction. Each flow channel includes an inlet and an outlet opposite to each other. A turbulence structure divides a cross-section of at least one of the flow channels into at least two diverging passages. The housing arranged on the substrate covers the inlets and includes an inlet port and a chamber. Accordingly, the number of fins may be increased in a fixed space, and each flow channel has a smaller cross-sectional area to increase flow velocity of a dielectric liquid. Moreover, this reduces the flow resistance of the dielectric liquid in a turbulent flow area in each flow channel to improve the heat dissipation efficiency.

### BACKGROUND OF THE INVENTION

### Technical Field

The present disclosure relates to a heat sink, in particular to a liquid-cooling heat sink with a turbulence structure which is used in an immersion cooling system and improves heat dissipation efficiency.

### Description of Related Art

Immersion cooling systems submerge heat-generating components (e.g., servers) in a dielectric liquid (a non-conductive fluid) in a sealed chassis and take away heat generated by the heat-generating components through the liquid properties of the dielectric liquid. The immersion cooling system is categorized into single-phase and two-phase systems. In the single-phase system, a pump is used to circulate the dielectric liquid in conjunction with a heat exchanger to achieve cooling, while the two-phase system employs a low-boiling-point dielectric liquid combined with a condenser to induce continuous phase change for cooling purposes.

In a related-art immersion cooling system, regardless of whether it's a single-phase or two-phase system, a heat sink with multiple fins is commonly placed on the heat-generating components to quickly conduct the generated heat to the fins, allowing the dielectric liquid to cool down the heat-generating components. However, due to limited spacing between the fins and the inherent viscosity of the dielectric liquid, fluidity of the dielectric liquid between the fins of the heat sink is often poor, or turbulent flow generated between the fins increases the flow resistance and affects the fluidity, thus greatly reducing the overall heat dissipation efficiency of the liquid-cooling system.

Therefore, it is imperative to find effective ways to enhance the fluidity of the dielectric liquid between the fins of the heat sink, reduce turbulent flow during liquid flow, and also reduce the spacing between the fins within a fixed space to increase the number of fins, thereby substantially improving the heat sink's cooling efficiency. Hence, recognizing these shortcomings in related art, the inventor conducted in-depth research and employed theoretical principles to address these issues, aiming to overcome the above shortcomings or deficiencies.

### SUMMARY OF THE INVENTION

It is a main objective of the present disclosure to increase the number of fins in a fin assembly within a fixed space, reduce a cross-sectional area of the flow channels to enhance flow velocity of the dielectric liquid, and at the same time reduce turbulent flow generated in the flow channel to lower flow resistance. As a result, the heat dissipation efficiency is significantly improved.

Accordingly, the present disclosure provides a liquid-cooling heat sink, including a substrate, a fin assembly, and a housing. The substrate has a longitudinal direction. The fin assembly is disposed on the substrate and includes a plurality of fins arranged at intervals to form a plurality of flow channels parallel to each other along the longitudinal direction. Each of the flow channels includes an inlet and an outlet opposite to each other, at least one of the flow channels is provided with a turbulence structure, and a cross-section of each flow channel at a location of the turbulence structure is divided into at least two diverging passages by the turbulence structure. The housing is disposed on the substrate and covers each of the inlets. The housing includes an inlet port. The housing and the substrate form a chamber together, and the chamber is disposed between the inlet port and each of the inlets.

According to one embodiment of the present disclosure, each of the fins includes a partition and two adjoining plates, wherein each of the adjoining plates of each of the fins extends vertically from a same side of the partition and contacts the partition of an adjacent one of the fins, and each of the flow channels is formed by one of the fins together with the partition of an adjacent one of the fins.

According to one embodiment of the present disclosure, the turbulence structure includes a plurality of protrusions, the protrusions are disposed on at least a portion of the fins, each of the protrusions protrudes from a corresponding one of the partitions, and a protruding length of each of the protrusions is less than or equal to an extension length of each of the adjoining plates.

According to one embodiment of the present disclosure, each of the fins is provided with at least one of the protrusions, and the fins provided with the protrusions and the rest of the fins are arranged alternately to form the fin assembly.

According to one embodiment of the present disclosure, the substrate further has a transverse direction perpendicular to the longitudinal direction, each of the protrusions is provided with a through hole, and each of the through holes extends through a corresponding one of the partitions and a corresponding one of the protrusions along the transverse direction.

According to one embodiment of the present disclosure, each of the fins is provided with at least one of the protrusions.

According to one embodiment of the present disclosure, the substrate further has a transverse direction perpendicular to the longitudinal direction, the turbulence structure includes a first limiting element, the first limiting element is inserted in the fins along the transverse direction, the first limiting element includes a first main plate and a plurality of first bars, each of the first bars includes a first extension section and a first inclined section, each of the first extension sections extends parallelly from the first main plate and is connected to a corresponding one of the first inclined sections, and each of the first inclined sections extends inclinedly toward the substrate from a corresponding one of the first extension sections.

According to one embodiment of the present disclosure, the turbulence structure further includes a second limiting element, the second limiting element is inserted in the fins along the transverse direction, the second limiting element includes a second main plate and a plurality of second bars, each of the second bars includes a second extension section and a second inclined section, each of the second extension sections extends parallelly from the second main plate and is connected to a corresponding one of the second inclined sections, and each of the second inclined sections extends inclinedly toward the substrate from a corresponding one of the second extension sections.

According to one embodiment of the present disclosure, the second limiting element is located between the first limiting element and the substrate, a longitudinal length of the first main plate is greater than a longitudinal length of the second main plate, each of the first inclined sections forms a first inclined angle with the first main plate, each of the second inclined sections forms a second inclined angle with the second main plate, and the first inclined angle is smaller than the second inclined angle.

In one embodiment of the present disclosure, a diversion element is further included, wherein the diversion element is disposed in the housing and includes a plurality of diverging channels, and the inlet port communicates with the chamber and the inlets through the diverging channels.

In the present disclosure, the liquid-cooling heat sink with the turbulence structure achieves effective heat dissipation by forcing the dielectric liquid to pass through the flow channels of the fin assembly via the inlet port and the chamber for heat exchange. Moreover, at least one of the flow channels is provided with the turbulence structure. A cross-section of each flow channel at a location of the turbulence structure is divided by the turbulence structure into at least two diverging passages. Accordingly, when the dielectric liquid flows into the flow channels, the dielectric liquid encounters the obstruction from the turbulence structure and is compelled to split and flow into the diverging passages. Such a configuration reduces a cross-sectional area of the flow channels, increasing the flow velocity of the dielectric liquid and minimizing turbulent flow to lower flow resistance in each flow channel. Additionally, this configuration also enhances the chances of the dielectric liquid flowing through a bottom of the flow channels (i.e., on a side close to the heat-generating component), thereby significantly improving the overall heat dissipation efficiency.

### BRIEF DESCRIPTION OF THE DRAWINGS

FIG. 1 is a perspective view illustrating a first embodiment of the present disclosure.

FIG. 2 is a perspective exploded view illustrating two of fins according to the first embodiment of the present disclosure.

FIG. 3 is a cross-sectional side view illustrating the first embodiment of the present disclosure.

FIG. 4 is a cross-sectional top view illustrating the first embodiment of the present disclosure.

FIG. 5 is a cross-sectional side view illustrating the first embodiment of the present disclosure in use.

FIG. 6 is a perspective view illustrating a second embodiment of the present disclosure.

FIG. 7 is a perspective exploded view illustrating three of the fins according to the second embodiment of the present disclosure.

FIG. 8 is a cross-sectional side view illustrating the second embodiment of the present disclosure.

FIG. 9 is a cross-sectional side view from another viewing angle according to the second embodiment of the present disclosure.

FIG. 10 is a perspective view according to a third embodiment of the present disclosure.

FIG. 11 is a perspective exploded view of part of a fin assembly according to the third embodiment of the present disclosure.

FIG. 12 is a perspective view of the fin assembly according to the third embodiment of the present disclosure.

FIG. 13 is a cross-sectional side view according to the third embodiment of the present disclosure.

### DETAILED DESCRIPTION

In the description of the present disclosure, it is to be understood that the directional terms such as “front”, “rear”, “left”, “right”, “front”, “rear”, “end”, “longitudinal”, “horizontal”, “vertical”, “top”, and “bottom”, indicate the orientation or positional relationship based on the orientation or positional relationship shown in the drawings. The directional terms are only for the convenience of describing the present disclosure and simplifying the description. The directional terms do not indicate or imply that the devices or components referred to must have specific orientations, be constructed or operated in specific orientations. Therefore, the directional terms should not be construed as limitations on the present disclosure.

As used in the present disclosure, terms such as “first”, “second”, “third”, “fourth”, and “fifth” are employed to describe various elements, components, regions, layers, and/or parts. These terms should not be construed as limitations on the mentioned elements, components, regions, layers, and/or parts. Instead, they are used merely for distinguishing one element, component, region, layer, or part from another. Unless explicitly indicated in the context, the usage of terms such as “first”, “second”, “third”, “fourth”, and “fifth” does not imply any specific sequence or order.

A detailed description and technical content of the present disclosure are described as follows with the accompanying drawings. However, these drawings are provided for illustrative purposes and not intended to limit the protection scope of the present disclosure.

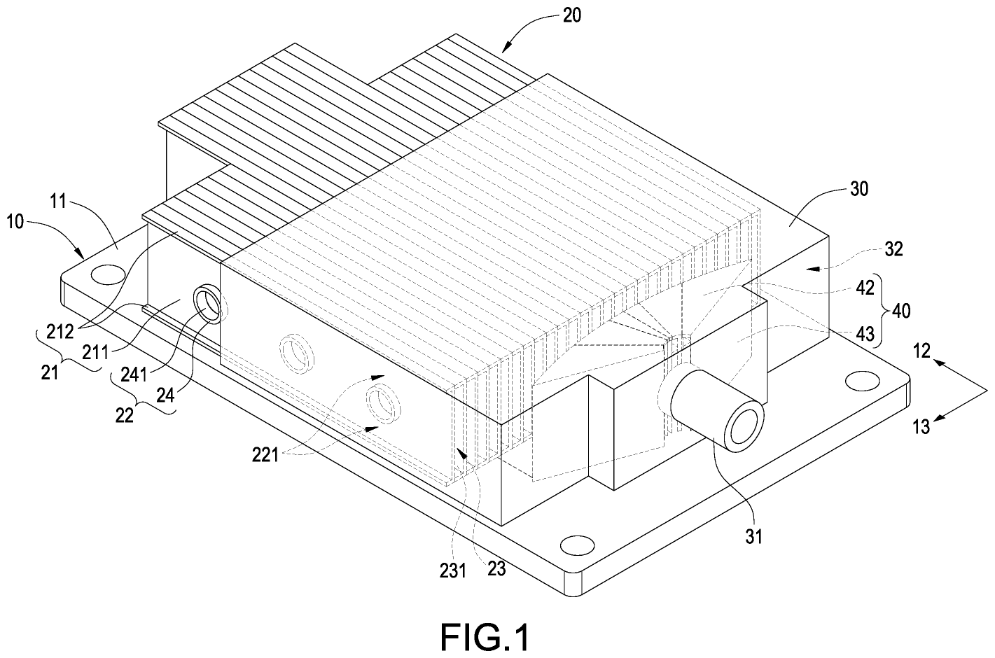

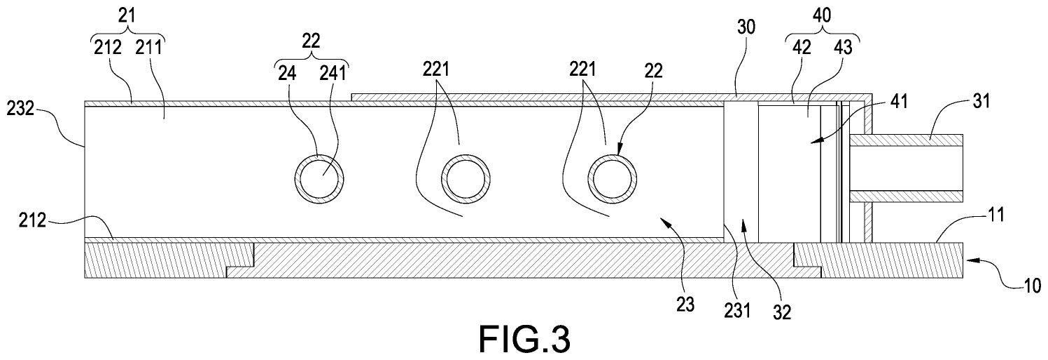

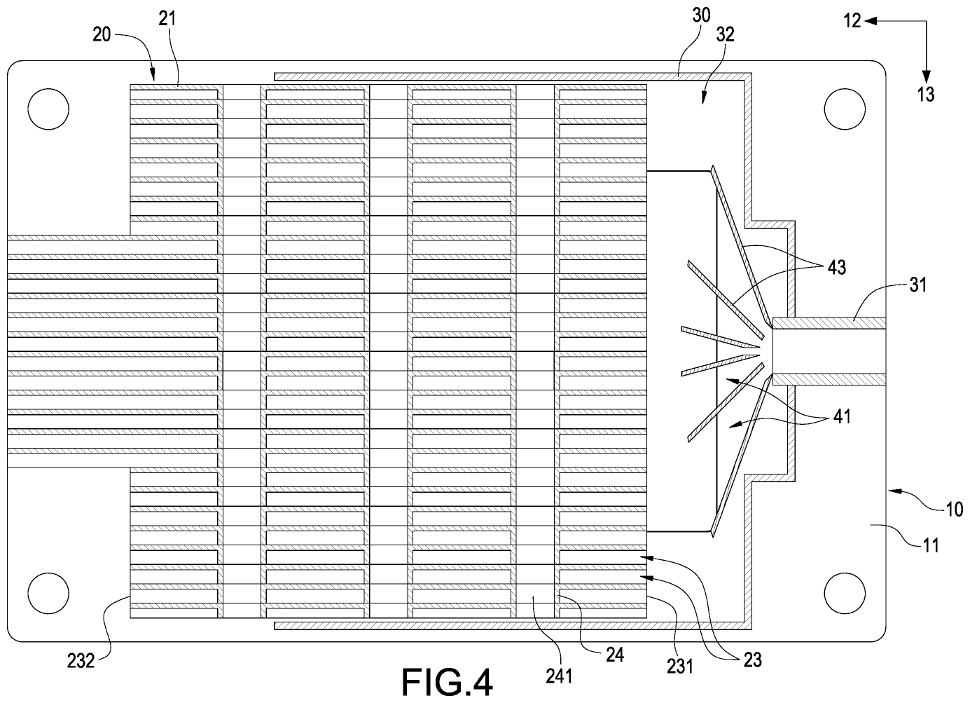

The present disclosure provides a liquid-cooling heat sink with a turbulence structure, for use in an immersion liquid cooling system, and is attached to a heat-generating component B soaked in a dielectric liquid A, so that the heat energy generated by the heating element B is transferred to the dielectric liquid A for heat dissipation. Please refer to FIGS. 1, 2, 3, 4, and 5, illustrating the liquid-cooling heat sink with the turbulence structure according to a first embodiment of the present disclosure, which mainly includes a substrate 10, a fin assembly 20, and a housing 30.

The substrate 10 is made of a material with desirable thermal conductivity, such as aluminum, copper, gold, tungsten, or alloys of the aforementioned metals, but the present disclosure is not limited the above-mentioned materials. In the present embodiment, the substrate 10 has a rectangular shape, but the shape of the substrate 10 may be adjusted according to the shape and size of the heat-generating component B or other requirements, so the present disclosure is not limited in this regard. The substrate 10 has an adhesive surface (not labeled in the drawings) and an installation surface 11 opposite to each other. The adhesive surface is used to attach to the heat-generating component B, so that the substrate 10 may quickly absorb heat generated by the heat-generating component B through the adhesive surface. The substrate 10 has a longitudinal direction 12 and a transverse direction 13 which are defined to be perpendicular and coplanar with each other. In the present embodiment, a long side of the substrate 10 extends along the longitudinal direction 12, while a short side of the substrate extends along the transverse direction 13.

The fin assembly 20 is positioned on the installation surface 11 of the substrate 10. The fin assembly 20 is made of a material with desirable thermal conductivity, such as aluminum, copper, gold, tungsten, or alloys of the aforementioned metals, but not limited to these materials. The fin assembly 20 includes a plurality of fins 21. The fins 21 are arranged at intervals to form a plurality of flow channels 23 parallel to each other along the longitudinal direction 12. Each of the flow channels 23 has an inlet 231 and an outlet 232 opposite to each other.

In the present embodiment, each fin 21 is formed through pressing/stamping and includes a partition 211 and two adjoining plates 212. The adjoining plates 212 of each fin 21 extend vertically from the same side of the partition 211 and contact the partition 211 of the adjacent fin 21. Specifically, the adjoining plates 212 are positioned on upper and lower sides of the partition 211, so that the fin 21 is in a “]” shape. The fins 21 are welded and fixed side by side in sequence along the transverse direction 13 toward the same direction to form the fin assembly 20. As a result, each flow channel 23 is formed by one fin 21 together with the partition 211 of the adjacent fin 21. However, the present disclosure is not limited to the disclosed fin assembly 20, and the shape and fixing method of the fins 21 may have various other embodiments. The shape, quantity, arrangement, and combination of the fins 21 in the fin assembly 20 are not limiting.

At least one of the flow channels 23 is provided with a turbulence structure 22, and a cross-section of each flow channel 23 at a location of the turbulence structure 22 is divided into at least two diverging passages 221 by the turbulence structure 22. In the present embodiment, the turbulence structure 22 is installed in all the flow channels 23, and the cross-section of each flow channel 23 is divided into two diverging passages 221 by the turbulence structure 22.

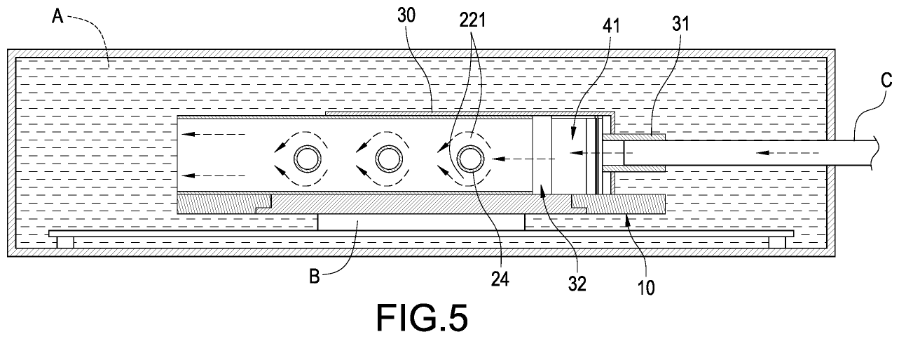

The housing 30 is disposed on the installation surface 11 of the substrate 10 and at least covers the inlets 231 of the fin assembly 20. Therefore, the housing 30 may also cover the entire fin assembly 20. In the present embodiment, the housing 30 may be made of a metal material, but it may also be made of plastic or other materials. A front side of the housing 30 includes an inlet port 31. The inlet port 31 is designed as a hollow tubular structure for easy connection to a flexible hose C of a pump (not illustrated), so that the dielectric liquid A is pushed by the pump to enter the inlet port 31 through the flexible hose C, as shown in FIG. 5. The inlet port 31 may be integrally formed with the housing 30 or assembled separately and then fixed to the housing 30. An inner side of the housing 30 and the installation surface 11 of the substrate 10 jointly form a chamber 32. The chamber 32 is located between the inlet port 31 and each inlet 231. This arrangement allows the dielectric liquid A to enter the inlets 231 from the inlet port 31 through the chamber 32.

As a result, the flexible hose C directly communicates with the inlet port 31, so that the dielectric liquid A, that is pushed by the pump and enters the inlet port 31 from the flexible hose C, flows from the chamber 32 into the fin assembly 20 through the inlets 231. The dielectric liquid A uniformly passes through the flow channels 23 of the fin assembly 20 to force the dielectric liquid A to flow through the fins 21 for heat exchange, thereby achieving desirable heat dissipation. Further, by having the turbulence structure 22 in at least one of the flow channels 23, the cross section of each flow channel 23, where the turbulence structure is located, is divided into at least two diverging passages 221, so that when the dielectric liquid A flows into each flow channel 23, the dielectric liquid A is forced to split into the diverging passages 221 due to the obstruction of the turbulence structure 22, thereby reducing the cross-sectional area of the flow channel 23 to increase the flow velocity of the dielectric liquid A in each flow channel 23, while minimizing turbulent flow generated in each flow channel 23 to lower flow resistance. Moreover, this arrangement enhances the chances of the dielectric liquid A flowing through a bottom of the flow channels 23 (i.e., on a side close to the heat-generating component B), thereby effectively improving the heat dissipation efficiency.

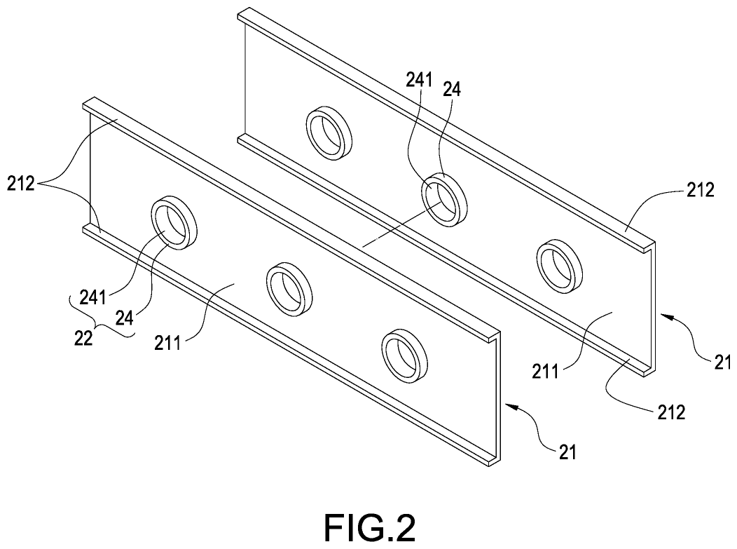

Referring to FIGS. 2, 3, and 4 for further elaboration, the turbulence structure 22 includes a plurality of protrusions 24. In the present embodiment, each protrusion 24 is disposed on one of the fins 21, and each fin 21 is provided with at least one protrusion 24. In the present embodiment, there are three protrusions 24 disposed on each fin 21 and arranged at intervals along the longitudinal direction 12, but the present disclosure is not limited to this arrangement. The number and arrangement of the protrusions 24 on each fin 21 may be adjusted according to a width and a longitudinal length of the fin 21.

Each protrusion 24 protrudes from the corresponding partition 211. In the present embodiment, a protruding direction of each protrusion 24 is the same as an extension direction of the adjoining plate 212, but in other embodiments, they may be opposite directions. A protruding length of each protrusion 24 is less than or equal to an extension length of each adjoining plate 212, so as to ensure that each adjoining plate 212 abuts against the partition 211 of the adjacent fin 21 to form the flow channel 23. Each protrusion 24 has a through hole 241, and each through hole 241 extends through the corresponding partition 211 and the corresponding protrusion 24 along the transverse direction 13. Specifically, the protrusions 24 and the through holes 241 in the present embodiment are formed by a hole punching process.

It should be noted that although the protrusions 24 shown in this embodiment are circular in shape, the protrusions 24 may also be rectangular, elliptical, drop-shaped, rhombus, triangular, polygonal or other undisclosed shapes. The shapes of the protrusions 24 are not limiting.

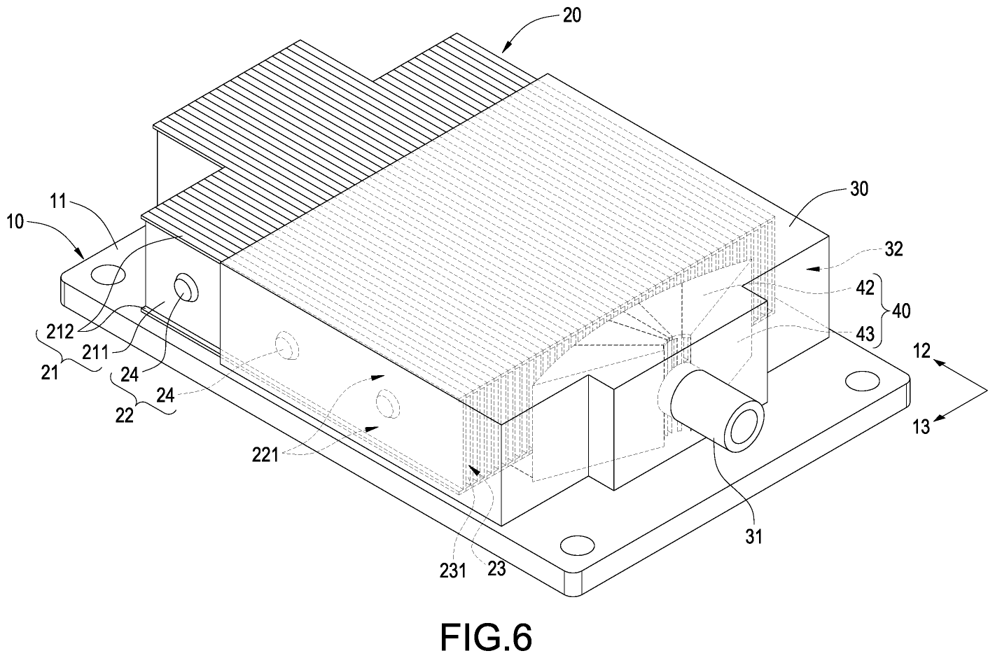

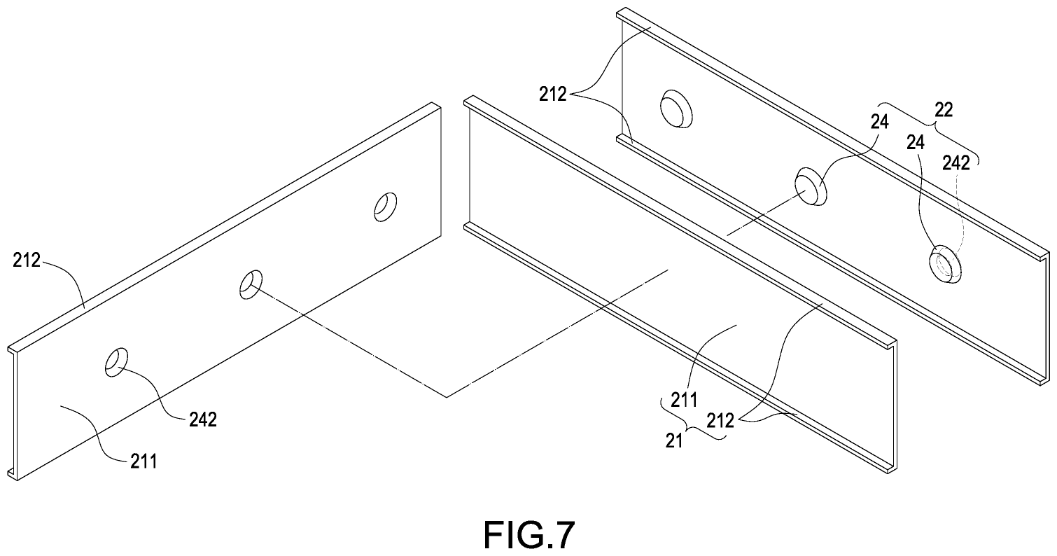

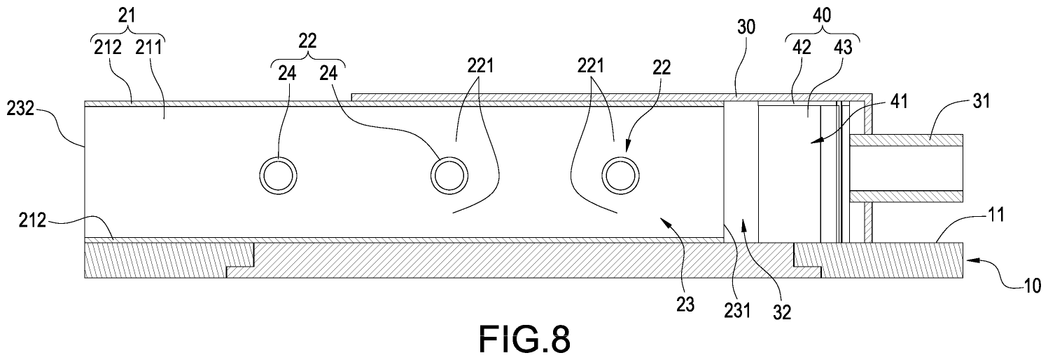

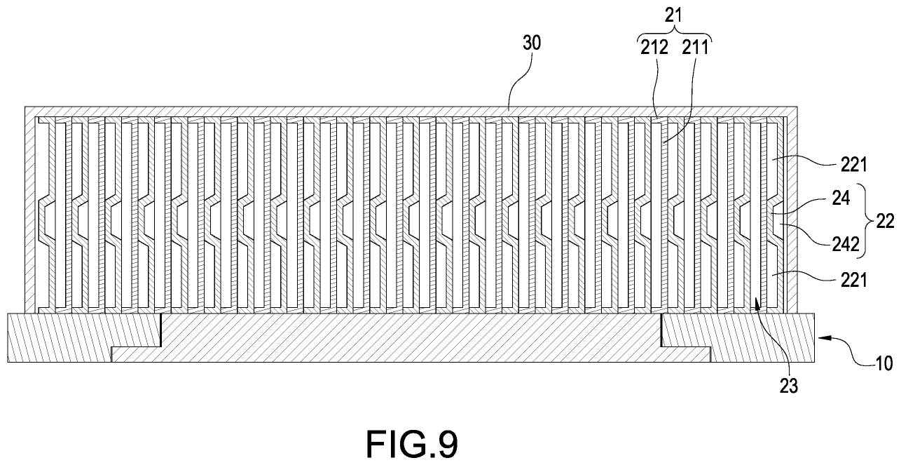

Please refer to FIGS. 6, 7, 8, and 9 which illustrate a second embodiment of the present disclosure. The second embodiment differs primarily from the first embodiment in terms of the structure and arrangement of the protrusions 24. Therefore, the same details are omitted here for brevity, and the differences are described in detail as follows.

In the present embodiment, the protrusions 24 are disposed at least on some of the fins 21, and each of the fins 21 is provided with at least one protrusion 24. In this embodiment, there are three protrusions 24 disposed on the fins 21 and arranged at intervals along the longitudinal direction 12. The fins 21 provided with the protrusions 24 and the rest of the fins 21 are arranged alternately to form the fin assembly 20. However, the present disclosure is not limited to the above arrangement. For example, the number and arrangement of the protrusions 24 disposed on the fins 21 may vary according to a width and a longitudinal length of the fin 21. The arrangement of the fins 21 provided with the protrusions and the rest of the fins 21 may also be adjusted according to different requirements.

Thus, in this embodiment, the fins 21 provided with the protrusions 24 and the rest of the fins 21 are arranged alternately. Therefore, compared with the first embodiment, apart from a portion of the dielectric liquid A being forced to flow through the diverging passages 221 by the obstruction of the turbulence structure 22 to increase the flow velocity, reduce the generated turbulent flow, and increase the chances of the dielectric liquid A flowing through the bottom of the flow channels 23, the rest of the dielectric liquid A is not obstructed by the turbulence structure 22 and may effectively transfer heat upward in the flow channels 23 during flow. Such a design combines the advantages of the first embodiment and the advantages of the related-art fin assembly 20, thereby avoiding the drawback of the first embodiment where the presence of the turbulence structure 22 in all the flow channels 23 affects the upward heat transfer.

It should be noted that the protrusions 24 shown in this embodiment are formed by stamping/pressing. Hence, unlike the protrusion 24 of the first embodiment which forms the through hole 241, the protrusion 24 of the present embodiment forms a recess 242. However, this difference is solely due to the different processing methods for the protrusions 24. The protrusions 24 formed by the two processing methods may obviously achieve the same turbulence effect. Moreover, the processing methods for the protrusions 24 in both embodiments should be interchangeable.

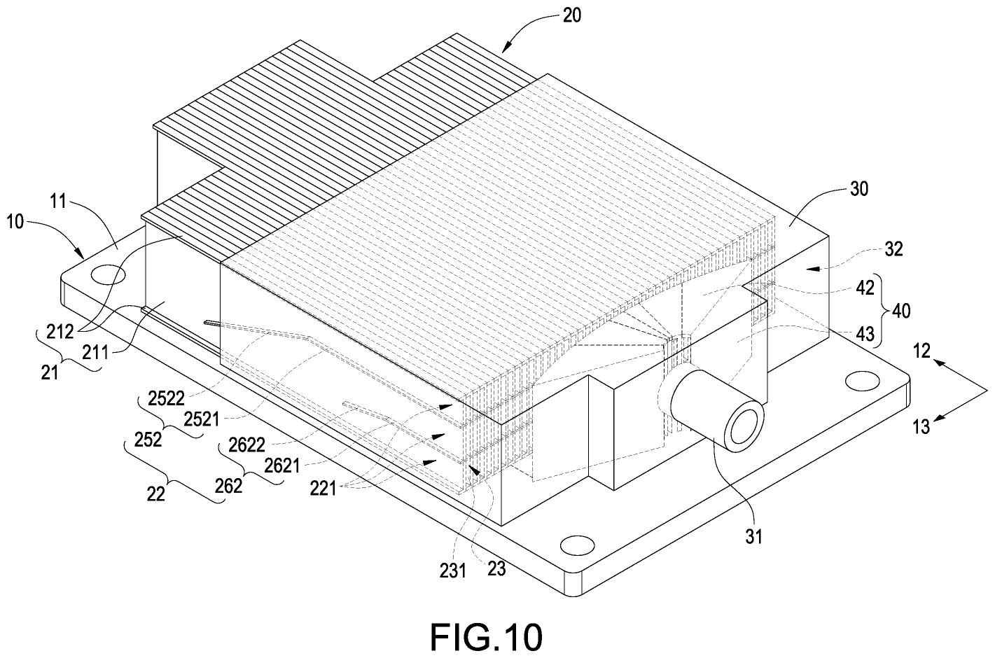

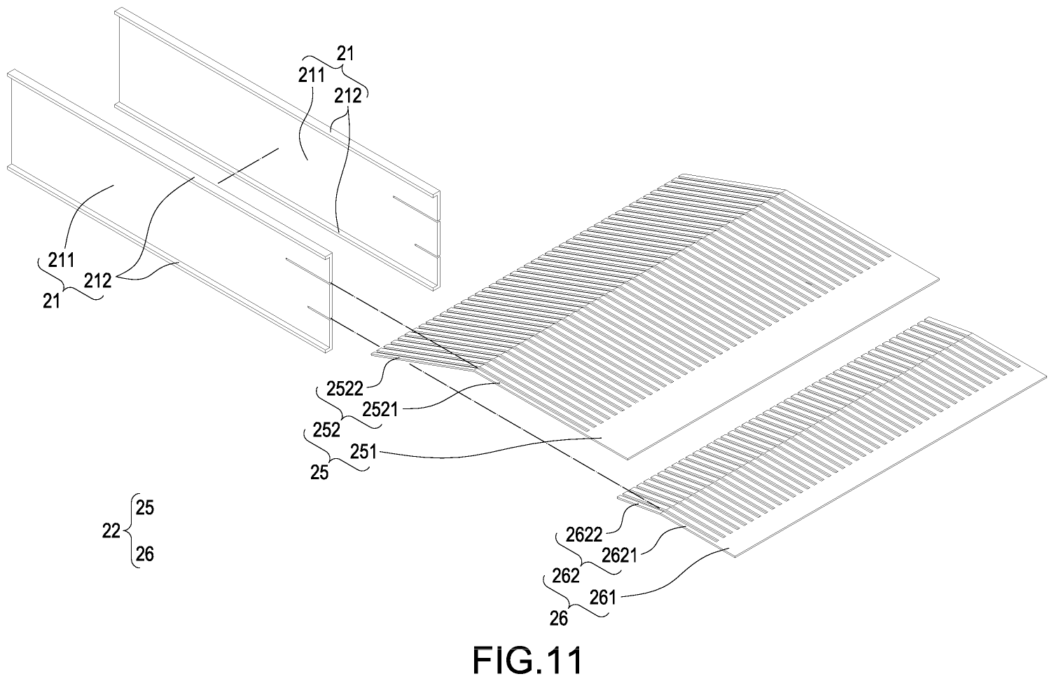

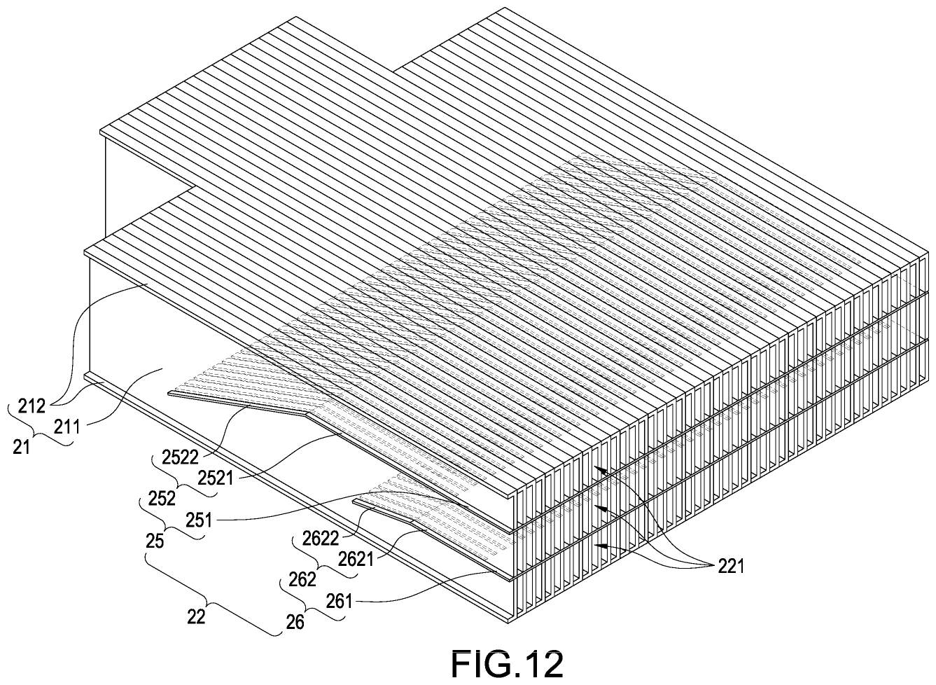

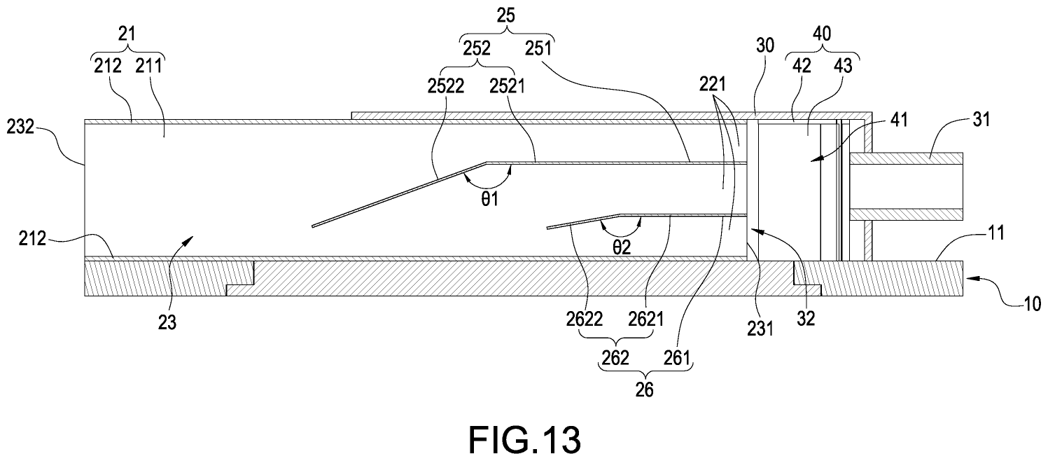

Please refer to FIGS. 10, 11, 12, and 13, which show a third embodiment of the present disclosure. The main difference between the present embodiment and the first embodiment lies in the structure and position of the turbulence structure 22. Therefore, the same details are omitted here for brevity, and the differences are described in detail as follows.

In this embodiment, the turbulence structure 22 includes at least a first limiting element 25. The first limiting element 25 is inserted in the fins 21 along the transverse direction 13, so that the cross-section of each flow channel 23, at a location where the turbulence structure 22 is located, is divided into two diverging passages 221. Specifically, the first limiting element 25 includes a first main plate 251 and a plurality of first bars 252. The first main plate 251 is rectangular. Each first bar 252 includes a first extension section 2521 and a first inclined section 2522, and each first extension section 2521 extends parallelly from the first main plate 251 to be connected to the corresponding first inclined section 2522. Each first inclined section 2522 extends inclinedly toward the substrate 10 from the corresponding first extension section 2521, so as to form a first inclined angle θ1 with the first main plate 251.

In some embodiments, the turbulence structure 22 further includes a second limiting element 26. The second limiting element 26 is inserted in the fins 21 along the transverse direction 13, so that the cross-section of each flow channel 23, at the location of the turbulence structure 22, is divided into three diverging passages 221 by the second limiting element 26 along with the first limiting element 25. Specifically, the second limiting element 26 includes a second main plate 261 and a plurality of second bars 262. The second main plate 261 is rectangular. Each second bar 262 includes a second extension section 2621 and a second inclined section 2622, and each second extension section 2621 extends parallelly from the second main plate 261 to be connected to the corresponding second inclined section 2622. Each second inclined section 2622 extends inclinedly toward the substrate 10 from the corresponding second extension section 2621, so as to form a second inclined angle θ2 with the second main plate 261.

In the present embodiment, the second limiting element 26 is positioned parallelly between the first limiting element 25 and the substrate 10. A longitudinal length of the first main plate 251 is greater than a longitudinal length of the second main plate 261, and the first inclined angle θ1 is smaller than the second inclined angle θ2. Of course, the relative positions of the first limiting element 25 and the second limiting element 26 are not limited to the above descriptions, and those skilled in the art would be able to make corresponding adjustments according to requirements.

Thereby, in the present embodiment, through the obstruction and restriction of the first limiting element 25 and the second limiting element 26, the dielectric liquid A, upon entering each flow channel 23, splits into three diverging passages 221, that is, the upper, middle and lower diverging passages 221. The dielectric liquid A flowing into the lower diverging passages 221 and the middle diverging passage 221 encounters obstruction and restriction from the second inclined sections 2622 and the first inclined sections 2522, and therefore flows toward the bottom of the flow channels 2. This forces the dielectric liquid A to come into direct contact with the bottom of the flow channels 23 for heat exchange, thereby further improving heat dissipation efficiency and greatly reducing generation of turbulent flow.

In detail, each embodiment of the present disclosure further includes a diversion element 40. The diversion element 40 shown in the drawings of the present disclosure is disposed inside the housing 30 and accommodated within the chamber 32, but the present disclosure is not limited to this arrangement. The diversion element 40 includes a plurality of diverging channels 41, and the inlet port 31 communicates with the chamber 32 and the inlets 231 through the diverging channels 41. Taking FIG. 5 as an example, the dielectric liquid A, that is pushed by the pump and enters the inlet port 31 from the flexible hose C, splits through the diverging channels 41 and flows into the chamber 32. Then, the dielectric liquid A flows into the fin assembly 20 through the inlets 231. This ensures that the dielectric liquid A uniformly passes through the flow channels 23 of the fin assembly 20, forcing the dielectric liquid A to flow through the fins 21 to perform heat exchange for good heat dissipation. Moreover, the dielectric liquid A is pushed by the pump, and the flexible hose C is directly connected to the inlet port 31, so the dielectric liquid A can be forced to flow through the flow channels 23 of the fin assembly 20. Consequently, in a fixed space of the liquid-cooling heat sink, a spacing between the fins 21 is reduced, and the number of the fins 21 is increased at the same time, which is more conducive to improving the heat dissipation efficiency.

Moreover, the diversion element 40 shown in the present disclosure is welded on an inner side of the housing 30 and includes a connection plate 42 and a plurality of barrier plates 43. The connection plate 42 is generally fan-shaped. Each barrier plate 43 is vertically connected to a bottom of the connection plate 42, and the barrier plates 43 are radially arranged from the inlet port 31 toward the fin assembly 20.

In the liquid-cooling heat sink with the turbulence structure of the present disclosure, through the flexible hose C directly communicating with the inlet port 31, the dielectric liquid A, that is pushed by the pump and enters the inlet port 31 from the flexible hose C, splits through the diverging channels 41 and flows into the chamber 32. Then, the dielectric liquid A flows into the fin assembly 20 through the inlets 231. Thus, the dielectric liquid A may uniformly pass through the flow channels 23 of the fin assembly 20, forcing the dielectric liquid A to flow through the fins 21 to perform heat exchange for good heat dissipation. Moreover, by providing the turbulence structure 22 in at least one of the flow channels 23, the cross section of each flow channel 23 at the location of the turbulence structure is divided into at least two diverging channels 221. As a result, when the dielectric liquid A flows into the flow channels 23, the dielectric liquid A is forced to split into the diverging passages 221 due to the obstruction from the turbulence structure 22. Such a configuration reduces a cross-sectional area of the flow channels 23, thus increasing the flow velocity of the dielectric liquid A in each flow channel 23. At the same time, the turbulent flow generated by the dielectric liquid A in each flow channel 23 is reduced to lower the flow resistance, and the chances of the dielectric liquid A flowing through the bottom of the flow channels 23 (that is, on the side close to the heat-generating component B) are increased, thus effectively enhancing the heat dissipation efficiency.

In summary, the present disclosure may also have other various embodiments, without departing from the spirit and essence of the present disclosure, those skilled in the art may make changes and modifications according to the present disclosure. However, such changes and modifications should be deemed to fall within the protection scope of the patent disclosure.

What is claimed is:

1. A liquid-cooling heat sink, comprising:
a substrate, comprising a longitudinal direction;
a fin assembly, disposed on the substrate, comprising a plurality of fins arranged spacedly to define a plurality of flow channels parallel to each other along the longitudinal direction, each of the flow channels comprising an inlet and an outlet opposite to each other, and a turbulence structure disposed in at least one of the flow channels, wherein a cross-section of each of the flow channels at the turbulence structure is divided into at least two diverging passages by the turbulence structure; and
a housing, disposed on the substrate and covering each of the inlets, comprising an inlet port, wherein a chamber is defined by the housing and the substrate together, and the chamber is located between the inlet port and each of the inlets.

2. The liquid-cooling heat sink according to claim 1, wherein each of the fins comprises a partition and two adjoining plates, wherein each of the adjoining plates of one of the fins extends vertically from a same side of the partition and contacts the partition of another one of the fins adjacent to each other, and one of the flow channels is defined by the one of the fins and the partition of the another one of the fins.

3. The liquid-cooling heat sink according to claim 2, wherein the turbulence structure comprises a plurality of protrusions, the protrusions are disposed on at least a portion of the fins, each of the protrusions protrudes from one of the partitions correspondingly, and a protruding length of each of the protrusions is less than or equal to an extension length of each of the adjoining plates.

4. The liquid-cooling heat sink according to claim 3, wherein at least one of the protrusions is disposed on the fins, and the fin assembly is structured in a manner of the fins provided with the protrusions and rest of the fins being arranged alternately.

5. The liquid-cooling heat sink according to claim 3, wherein the substrate further comprises a transverse direction perpendicular to the longitudinal direction, each of the protrusions comprises a through hole, and the through hole extends through the partition and one of the protrusions along the transverse direction.

6. The liquid-cooling heat sink according to claim 3, wherein at least one of the protrusions is disposed on each of the fins.

7. The liquid-cooling heat sink according to claim 1, wherein the substrate further comprises a transverse direction perpendicular to the longitudinal direction, the turbulence structure comprises a first limiting element, the first limiting element is inserted in the fins along the transverse direction, the first limiting element comprises a first main plate and a plurality of first bars, each of the first bars comprises a first extension section and a first inclined section, the first extension section extends parallelly from the first main plate and is connected to the first inclined section correspondingly, and the first inclined section extends inclinedly toward the substrate from the first extension section correspondingly.

8. The liquid-cooling heat sink according to claim 7, wherein the turbulence structure further comprises a second limiting element, the second limiting element is inserted in the fins along the transverse direction, the second limiting element comprises a second main plate and a plurality of second bars, each of the second bars comprises a second extension section and a second inclined section, the second extension section extends parallelly from the second main plate and is connected to the second inclined section correspondingly, and the second inclined section extends inclinedly toward the substrate from the second extension section correspondingly.

9. The liquid-cooling heat sink according to claim 8, wherein the second limiting element is located between the first limiting element and the substrate, a longitudinal length of the first main plate is greater than a longitudinal length of the second main plate, a first inclined angle is defined between the first inclined section and the first main plate, a second inclined angle is defined between the second inclined section and the second main plate, and the first inclined angle is smaller than the second inclined angle.

10. The liquid-cooling heat sink according to claim 1, further comprising a diversion element, wherein the diversion element is disposed in the housing and comprises a plurality of diverging channels, and the inlet port communicates with the chamber and the inlets through the diverging channels.
